(19) United States
(12) Patent Application Publication
(10) Pub. No.: US 2025/0323659 A1
(43) Pub. Date: Oct. 16, 2025

(54) ANALOG-TO-DIGITAL CONVERTER AND CASCADED ANALOG-TO-DIGITAL CONVERTER

(71) Applicant: ams Sensors Germany GmbH, Jena (DE)

(72) Inventor: Akif UCAR, Dresden (DE)

(21) Appl. No.: 18/868,133

(22) PCT Filed: Mar. 13, 2023
(86) PCT No.: PCT/EP2023/056382

§ 371 Date: Nov. 21, 2024

(30) Foreign Application Priority Data
May 24, 2022 (DE) 102022113150.5

(51) Int. Cl. H03M 1/46

(52) U.S. Cl. CPC H03M 1/462

(57) ABSTRACT

The invention relates to an analog-to-digital converter (ADC), configured to convert an analog input signal to a digital output signal, the ADC comprising: an integrator configured to generate an integrated signal based on the analog input signal and subtrahend signals; and a quantizer configured to: receive the integrated signal from the integrator, generate the digital output signal; and generate a quantization error signal, wherein the ADC is further configured to, in a feedback loop: provide the integrated signal and the quantization error signal as the subtrahend signals to the integrator.

### SUMMARY

The present disclosure relates to an analog-to-digital-converter (ADC) and cascaded Analog to Digital Converters (ADCs).

A conventional ADC such as a sigma-delta modulator with a multi-bit internal quantizer has a wide range of possible applications. For example, it may be used in process control, high resolution data acquisition, sensor interfaces, or transceivers for wireless communication.

The sigma-delta modulator is a system with feedback that comprises a loop-filter, quantizer, and a digital-to-analog converter (DAC). The loop filter can consist of one or more integrators. The DAC provides a feedback signal to the integrator, which in turn integrates a difference between an input signal and the feedback signal to generate an integrated signal that is provided to the quantizer. During said processing, the digital-to-analog conversion of the DAC causes nonlinear errors and produces nonlinear signal distortions into the overall ADC response due to the mismatch within the DAC elements.

Furthermore, cascaded ADCs such as the common cascade MASH (Multi-Stage Noise-Shaping) and SMASH (Sturdy-MASH) delta-sigma modulators comprise multiple stages or loops, where for each stage a DAC is used for quantization error feed-in following from the previous stage. This requires extra circuitry and implies more power consumption.

It is therefore an object of the present invention to provide an improved analog-to-digital converter.

It is therefore another object of the present invention to provide an improved cascaded ADC topology.

The above objects are achieved by the subject-matter according to the independent claims. Further developments are defined in the dependent claims.

According to embodiments, an analog-to-digital converter (ADC) is configured to convert an analog input signal to a digital output signal. The ADC comprises an integrator configured to generate an integrated signal based on the input signal and subtrahend signals, and a quantizer that is configured to receive the integrated signal from the integrator, to generate the digital output signal, and to generate a quantization error signal. The ADC is further configured to, in a feedback loop, provide the integrated signal and the quantization error signal as the subtrahend signals to the integrator.

Providing the quantization error signal as input into the integrator instead of the commonly used quantizer output alleviates the need of a multi-bit digital-to-analog converter (DAC). This increases the linearity and prevents nonlinear errors and nonlinear signal distortions due to the multi-bit DAC.

In greater detail, the quantizer may comprise a SAR (successive approximation register) ADC. The usage of a SAR quantizer enables to obtain the quantization error that serves as input into the feedback loop. Due to the SAR quantizer's DAC there is no need for a multi-bit DAC as in common ADC topologies.

The integrator may generate the integrated signal by integrating a difference of the input signal and the subtrahend signals.

The ADC may further be based on a multi-bit sigma-delta quantization.

According to embodiments, a cascaded analog-to-digital converter (ADC) is configured to convert an analog input signal to a digital output signal. The cascaded ADC comprises a first loop and a second loop. The first loop comprises a first loop integrator configured to generate a first loop integrated signal based on the input signal and a first loop subtrahend signal, and a first loop quantizer comprising a SAR (successive approximation register) ADC. The first loop quantizer is being configured to receive the first loop integrated signal from the first loop integrator, to generate a first loop digital output signal, and to generate a first loop quantization error signal that is provided as a second loop input signal to the second loop of the cascaded ADC. The second loop comprises a second loop integrator configured to generate a second loop integrated signal based on the second loop input signal and a second loop subtrahend signal, and a second loop quantizer. The second loop quantizer is configured to receive the second loop integrated signal from the second loop integrator and to generate a second loop digital output signal. The cascaded ADC is further configured to provide as the first loop subtrahend signal an analog output signal of the first loop quantizer to the first loop integrator, and provide as the second loop subtrahend signal an analog output signal of the second loop quantizer to the second loop integrator.

The use of a SAR quantizer in the first loop of the cascaded ADC enables obtaining a quantization error on a DAC of the SAR quantizer that is sampled and feed in to the consequent loop without requiring an extra DAC as in common cascaded ADC topologies.

The cascaded ADC may be a Multi-Stage Noise-Shaping (MASH) Sigma-Delta ADC.

Furthermore, the cascaded ADC may be based on a multi-bit sigma-delta quantization.

According to embodiments, a cascaded analog-to-digital converter (ADC) configured to convert an analog input signal to a digital output signal is provided. The cascaded ADC comprises a first loop and a second loop. The first loop comprises a first loop integrator configured to generate a first loop integrated signal based on the input signal and a first loop subtrahend signal, and a first loop quantizer comprising a SAR (successive approximation register) ADC, the first loop quantizer. The first loop quantizer is being configured to receive the first loop integrated signal from the first loop integrator, to generate a first loop digital output signal, and to generate a first loop quantization error signal that is provided as a second loop input signal to the second loop of the cascaded ADC. The second loop comprises a second loop integrator configured to generate a second loop integrated signal based on the second loop input signal and a second loop subtrahend signal, and a second loop quantizer. The second loop quantizer is configured to receive the second loop integrated signal from the second loop integrator, and to generate a second loop digital output signal. The cascaded ADC is further configured to provide as the first loop subtrahend signal an analog output signal based on the first loop digital output signal and the second loop digital output signal to the first loop integrator, and provide as the second loop subtrahend signal an analog output signal of the second loop quantizer to the second loop integrator.

Similar to the cascaded ADC described above, said topology provides a quantization error that is sampled and fed in to the consequent loop without requiring an extra DAC as in common cascaded ADC topologies.

The cascaded ADC may be a Sturdy Multi-Stage Noise Shaping (SMASH) Sigma-Delta ADC.

The cascaded ADC may be based on a multi-bit sigma-delta quantization.

According to embodiments, an electronic device is provided. The electronic device comprises the above described ADC or the above described cascaded ADCs.

The electronic device may be selected from mobile communication devices, smartphones, wearable devices, and/or sensors.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIG. 1 is a schematic diagram illustrating an ADC according to embodiments.

FIG. 2 illustrates components of a first order ADC according to embodiments in more detail.

FIG. 3 illustrates components of a second order ADC according to embodiments in more detail.

FIG. 4 is a schematic diagram illustrating a cascaded MASH Sigma-Delta ADC according to embodiments.

FIG. 5 illustrates components of the cascaded MASH Sigma-Delta ADC in more detail.

FIG. 6 is a schematic diagram illustrating a cascaded SMASH Sigma-Delta ADC according to embodiments

FIG. 7 illustrates components of the cascaded SMASH Sigma-Delta ADC in more detail.

FIG. 8A is a schematic diagram illustrating an electronic device according to embodiments.

FIG. 8B is another schematic diagram illustrating an electronic device according to embodiments.

### DETAILED DESCRIPTION

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “over”, “on”, “above”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

As employed in this specification, the terms “coupled” and/or “electrically coupled” are not meant to mean that the elements must be directly coupled together-intervening elements may be provided between the “coupled” or “electrically coupled” elements. The term “electrically connected” intends to describe a low-ohmic electric connection between the elements electrically connected together. Furthermore, the term “connected” comprises a wireless as well as a wired coupling between elements.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

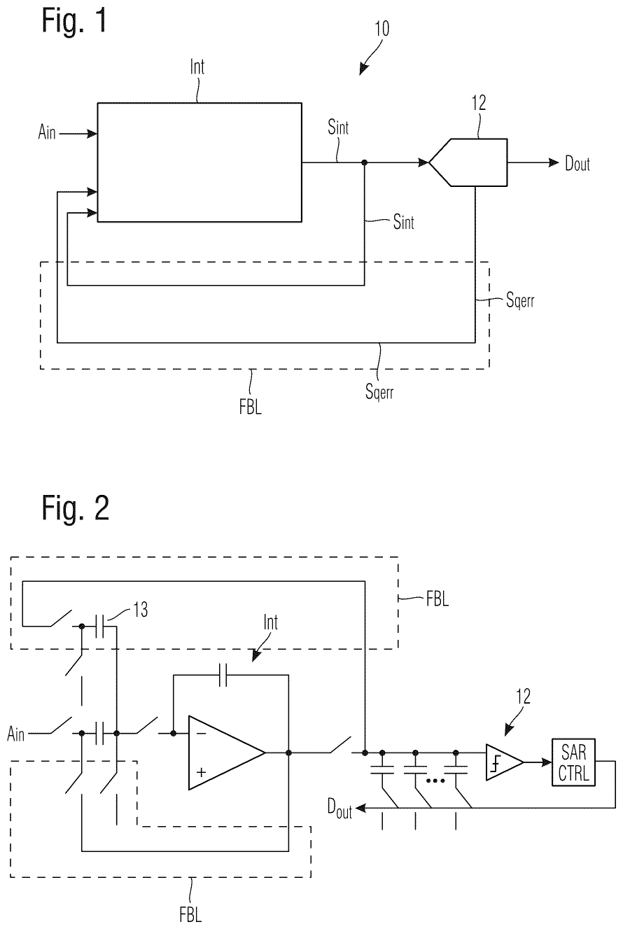

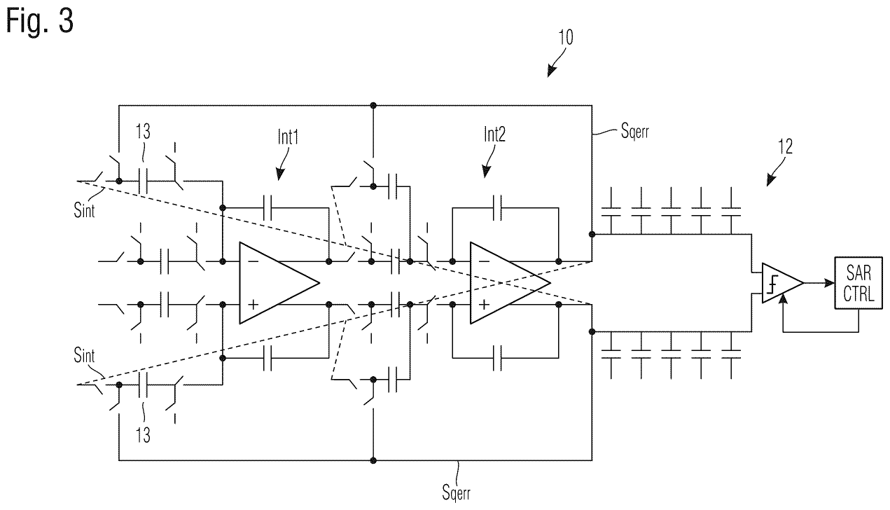

FIG. 1 is a schematic diagram illustrating the general setup of an ADC 10 according to embodiments. The ADC 10 converts an analog input signal Ain into a digital output signal Dout as shown by the respective arrows. The ADC 10 comprises an Integrator Int and a quantizer 12. The integrator Int shown in FIG. 1 is representative of several integrators Int, Int1, Int2 that may be included in the ADC 10. In this regard, the number of Integrators Int, Int1, Int2, . . . , Inti determines the order of the ADC 10. For example, FIG. 2 illustrates a first order ADC 10 with one integrator Int, while FIG. 3 illustrates a second order ADC 10 comprising two integrators Int1, Int2.

The integrator Int, Int1, Int2 generates an integrated signal Sint based on the input signal Ain and subtrahend signals, which are explained in detail later on.

The quantizer 12 receives the integrated signal Sint from the integrator Int, Int1, Int2 and generates the digital output signal Dout. Additional components such as digital filters 14 (not shown in FIG. 1) may be applied to further process the digital output signal Dout. In addition, the quantizer 12 generates a quantization error signal Sqerr, which is provided as an input signal to a feedback loop FBL. The feedback loop FBL is indicated by a dashed rectangle in FIG. 1.

Furthermore, as can be seen in FIG. 1, also the integrated signal Sint of the integrator Int (i.e., the input signal into the quantizer 12) is fed back into the feedback loop FBL. In this context, the quantization error signal Sqerr and the integrated signal Sint correspond to the subtrahend signals. They are received by the Integrator Int in the feedback loop FBL and further processed.

The topology of the exemplary ADC 10 according to present embodiments as shown in FIG. 1 differs from that of a conventional ADC, in that for the feedback loop a DAC is applied and the output of the quantizer is provided as a subtrahend signal instead of the quantization error signal Sqerr. For example, in a conventional ADC, usually a multi-bit quantizer is used that requires a multi-bit DAC, which in turn entails linearity issues that need to be compensated, e.g., via dynamic element matching techniques. The linearization requirements of such a multi-bit DAC amounts to more power consumption and a more complex circuitry limiting the ENOB (effective number of bits). For example, conventionally, for 4 a bit quantizer a DAC with 16 capacitors is required.

With a topology as illustrated in FIG. 1, it is possible to avoid the use of the multi-bit DAC and its multiple capacitors. Providing the quantization error signal Sqerr instead of the quantizer output enables using only one capacitor 13 in order to create the feedback for the multi-bit ADC 10.

According to embodiments, the quantizer 12 may comprise a SAR (successive approximation register) ADC that provides the quantization error signal Sqerr at the quantizers 12 input. FIG. 2 shows components of a first order ADC 10 according to embodiments in more detail. As can be seen in FIG. 2, the ADC 10 comprises the SAR ADC instead of an extra multi-bit DAC, as applied in common ADC topologies. Using the SAR ADC as a quantizer 12 allows extracting the residue and using the residue for all possible feedback connections in the ADC 10. The solutions for the linearity of the SAR ADC are more power efficient and less complex. Furthermore, re-using a DAC of the SAR ADC is more efficient. Providing the output of the integrator Int (i.e., the output of the last integrator Int or the input of the SAR ADC) in addition to the quantization error signal Sqerr as the subtrahend signals, the integrator Int, Int1, Int2 may generate the integrated signal Sint by integrating a difference of the input signal Ain and the subtrahend signals.

FIG. 3 shows a second order topology for an ADC 10 according to embodiments in more detail. In this illustrated example a 4-bit quantizer 12 is employed. The dashed lines indicate the integrated signal Sint of the second integrator Int2 that is provided as one of the subtrahend signals. In addition, as can be seen in FIG. 3, only the DAC of the SAR ADC is re-used for all the feedback.

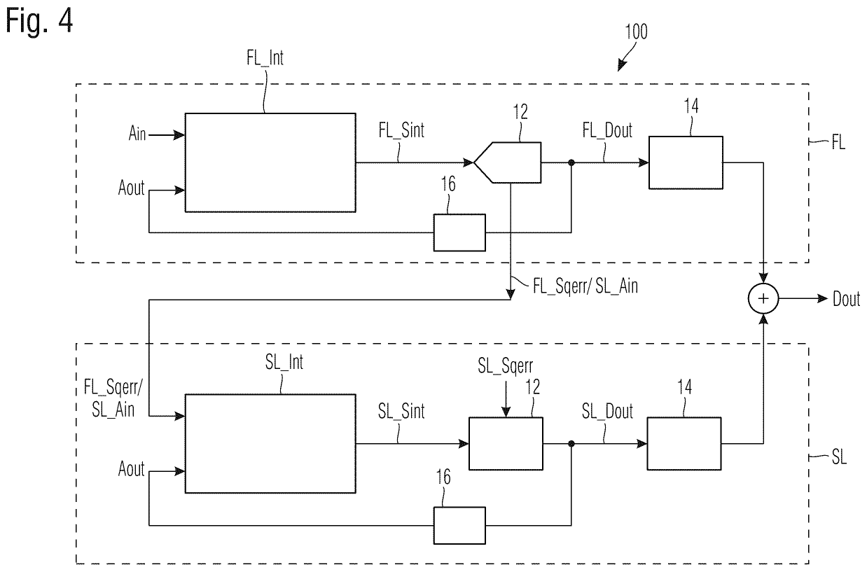

In the following further concepts using a SAR ADC in cascaded ADC topologies are described in detail with reference to FIGS. 4 to 7.

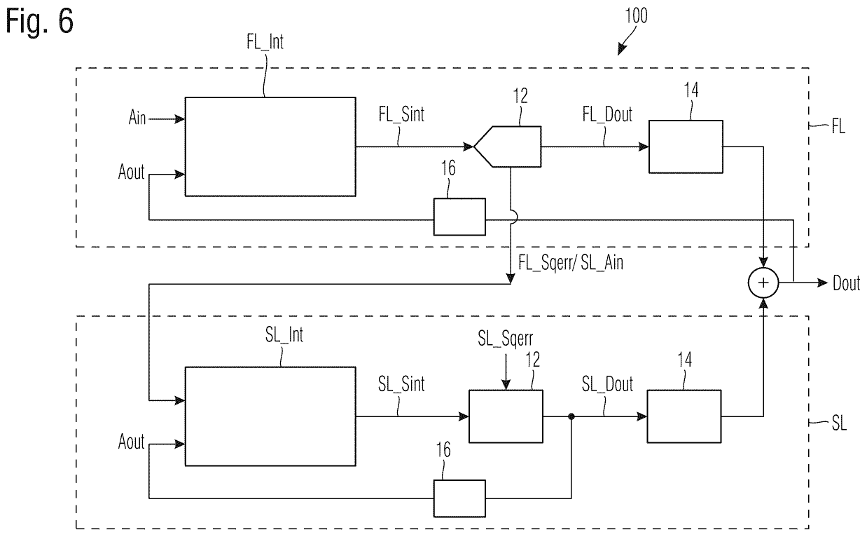

FIGS. 4 and 6 are schematic diagrams illustrating cascaded ADC topologies according to embodiments. The cascaded ADCs 100 illustrated in FIGS. 4 and 6 convert an analog input signal Ain to a digital output signal Dout as illustrated by respective arrows. The cascaded ADCs 100 both comprise a first loop FL and a second loop SL indicated by dashed rectangles in FIGS. 4 and 6. These examples are not limiting. More loops (which are also called stages) may be implemented.

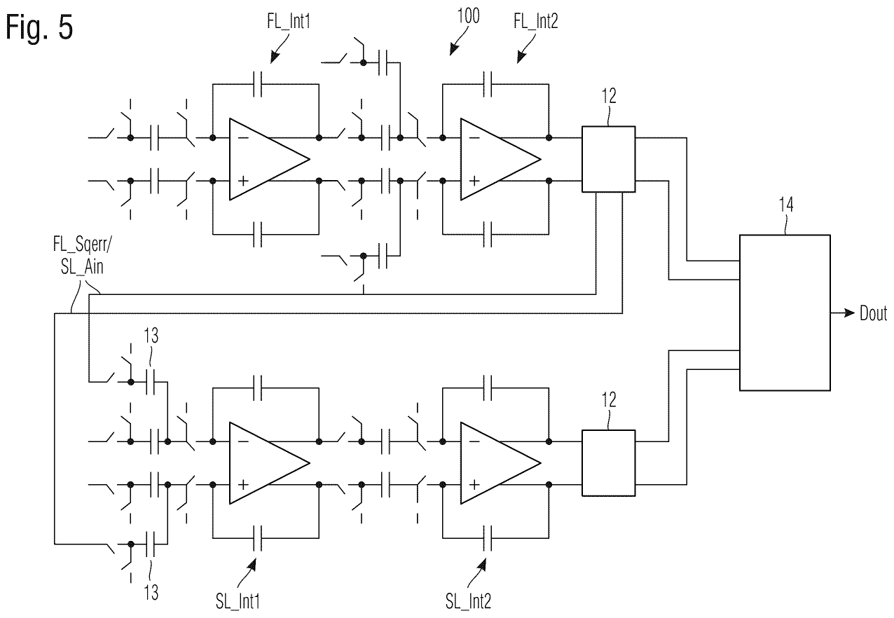

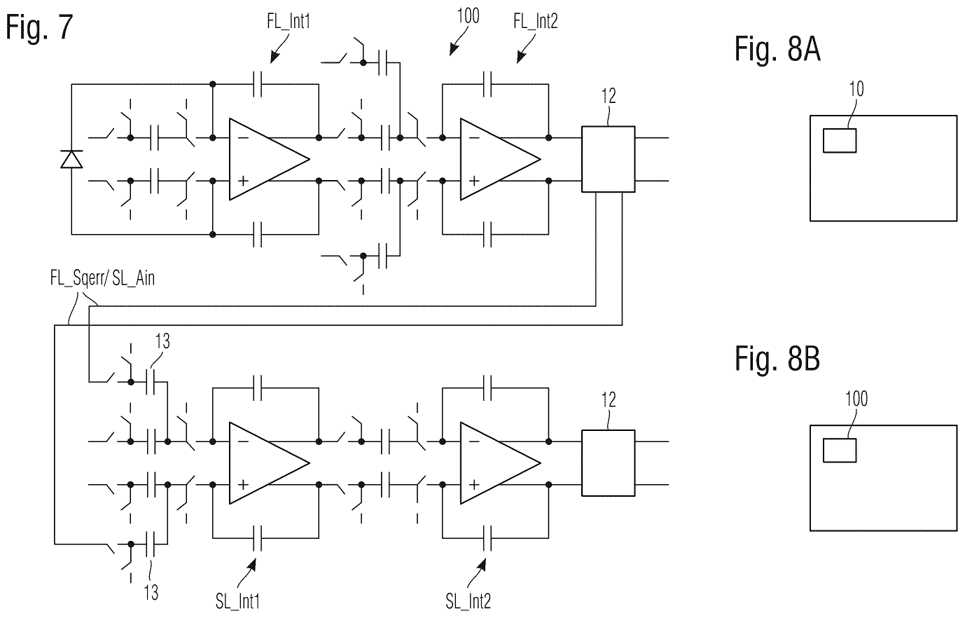

The first loop FL of the cascaded ADCs 100 as shown in FIGS. 4 and 6 comprises a first loop integrator FL_Int and a first loop quantizer 12. The first loop integrator FL_Int is representative of several first loop integrators FL_Int1, FL_Int2 that may be included in the cascaded ADCs 100. For example, FIGS. 5 and 7 show specific cascaded ADC topologies in more detail. FIGS. 5 and 7 show two first loop integrators FL_Int1, FL_Int2.

The first loop integrator FL_Int, FL_Int1, FL_Int2 may generate a first loop integrated signal FL_Sint based on the input signal Ain and a first loop subtrahend signal, which will be explained later on. In greater detail, the first loop integrator FL_Int, FL_Int1, FL_Int2 may generate the first loop integrated signal FL_Sint by integrating a difference of the input signal Ain and the subtrahend signal.

Furthermore, the first loop quantizer 12 comprises a SAR (successive approximation register) ADC, which receives the first loop integrated signal FL_Sint from the first loop integrator FL_Int, FL_Int1, FL_Int2. The first loop quantizer 12 generates a first loop digital output signal FL_Dout and a first loop quantization error signal FL_Sqerr. As illustrated in FIGS. 4 to 7, the first loop quantization error signal FL_Sqerr is provided as a second loop input signal SL_Ain into the second loop SL of the cascaded ADCs 100.

Using a SAR ADC as shown in FIGS. 4 to 7 allows extracting the quantization error inherently. Said error is fed back as the first loop quantization error signal FL_Sqerr. There is no need for an additional DAC as in conventional cascaded ADC topologies for multi-bit applications. Such an additional DAC has linearity issues that require further circuitry for compensation (such as dynamic element matching). Re-using the DAC of the SAR ADC allows keeping the circuitry simple by requiring only one capacitor for feedback.

This aspect is further illustrated in FIGS. 5 and 7, which present more detailed cascaded ADC topologies comprising two loops FL, SL. FIG. 5 corresponds to a so-called Multi-Stage Noise Shaping (MASH) Sigma-Delta ADC (also called a stage 2-2 MASH ADC) while FIG. 7 shows a Sturdy MASH Sigma-Delta ADC (also called a stage 2-2 SMASH ADC). Both topologies apply a 4-bit SAR ADC. As can be seen, the input of the quantization error signal FL_Sqerr comprises only one capacitor 13. In conventional topologies a DAC with 16 capacitors is required.

Turning to the second loop SL of the cascaded ADCs 100 shown in FIGS. 4 and 6, the second loop SL comprises a second loop integrator SL_Int and a second loop quantizer 12. Similar to the first loop integrator FL_Int, the second loop integrator SL_Int is representative of several second loop integrators, SL_Int1, SL_Int2 that can be included in the cascaded ADCs 100. For example, FIGS. 5 and 7 show two second loop integrators SL_Int1, SL_Int2.

The second loop integrator SL_Int, SL_Int1, SL_Int2 generates a second loop integrated signal SL Sint based on the second loop input signal SL_Ain and a second loop subtrahend signal. The second loop subtrahend signal will also be explained later on. Similar to the first loop Integrator FL_Int, FL_Int1, FL_Int2, the second loop integrator SL_Int, SL_Int1, SL_Int2 may generate the second loop integrated signal SL Sint by integrating a difference of the input signal SL_Ain (FL_Sqerr) and the subtrahend signal.

The second loop quantizer 12 receives the second loop integrated signal SL Sint from the second loop integrator SL_Int, SL_Int1, SL_Int2 and generates a second loop digital output signal SL_Dout. The second loop quantizer 12 also has a second loop quantization error SL Sqerr that can be provided to subsequent loops (not shown in FIGS. 4 to 7).

As indicated in FIGS. 4 and 6, the cascaded ADC topology can also include digital filters 14 that further process the first loop- and second loop digital output signals FL_Dout, SL_Dout.

The cascaded ADC 100 of FIG. 4 further provides as the first loop subtrahend signal an analog output signal Aout of the first loop quantizer 12 to the first loop integrator FL_Int, FL_Int1, FL_Int2. Moreover, it provides as the second loop subtrahend signal an analog output signal Aout of the second loop quantizer 12 to the second loop integrator SL_Int, SL_Int1, SL_Int2.

As illustrated in FIG. 4, each of the first- and second loops of the cascaded ADC 100 may comprise a DAC 16 in order to generate the analog output signal Aout.

The configuration as illustrated in FIGS. 4 and 5 pertains to the MASH Sigma-Delta ADC.

In contrast to the MASH ADC 100, the cascaded ADC 100 of FIG. 6 provides as the first loop subtrahend signal an analog output signal Aout based on the first loop digital output signal FL_Dout and the second loop digital output signal SL_Dout to the first loop integrator FL_Int, FL_Int1, FL_Int2. In addition, the cascaded ADC 100 of FIG. 6 provides as the second loop subtrahend signal an analog output signal Aout of the second loop quantizer 12 to the second loop integrator SL_Int, SL_Int1, SL_Int2.

As illustrated in FIG. 6, the first- and second loop of the cascaded ADC 100 comprises each a DAC 16 in order to generate the analog output signal Aout.

The configuration as illustrated in FIGS. 6 and 7 pertains to the SMASH Sigma-Delta ADC. The difference between the MASH topology and the SMASH topology is that in the SMASH ADC 100 the output of the second loop SL is coupled back into the first loop FL and there is no noise cancellation logic.

Both cascaded ADCs 100 may be based on a multi-bit sigma-delta quantization.

With such a topology as shown in FIGS. 4 to 7 it is possible to re-use a DAC of the SAR ADC, which alleviates the need for an extra multi-bit DAC in respective loops of the cascaded ADCs 100.

FIGS. 8A and 8B show schematic diagrams illustrating an electronic device 1 according to embodiments. The electronic device shown in FIG. 8A comprises the above described ADC 10. The electronic device 1 shown in FIG. 8B comprises one of the above described cascaded ADCs 100.

The electronic device may be selected from mobile communication devices, smartphones, wearable devices, and/or sensors.

Providing a ADC 10 or cascaded ADC 100 as described above in the electronic device 1 improves the overall power consumption and saves space as the ADC 10 or cascaded ADC 100 may be implemented without additional circuitry.

LIST OF REFERENCES

| | |
|---|---|
| 1 | electronic device |
| 10 | analog-to-digital converter |
| 12 | quantizer |
| 13 | capacitor |
| 14 | digital filter |
| 16 | digital-to-analog converter |
| 100 | cascaded analog-to-digital converter |
| Ain | analog input signal |
| Dout | digital output signal |
| Int, Int1, Int2 | integrator |
| Sint | integrated signal |
| Sqerr | quantization error signal |
| FBL | Feedback loop |
| FL | first loop |
| SL | second loop |
| FL_Int, FL_Int1, FL_Int2 | first loop integrator |
| SL_Int, SL_Int1, SL_Int2 | second loop integrator |
| FL_Sint | first loop integrated signal |
| SL_Sint | second loop integrated signal |
| FL_Dout | first loop digital output signal |
| SL_Dout | second loop digital output signal |
| FL_Sqerr | first loop quantization error signal |
| SL_Sqerr | second loop quantization error signal |
| SL_Ain | second loop analog input signal |
| Aout | analog output signal |

1. An analog-to-digital converter (ADC), configured to convert an analog input signal to a digital output signal, the ADC comprising:
an integrator configured to generate an integrated signal based on the analog input signal and subtrahend signals; and
a quantizer configured to:
receive the integrated signal from the integrator,
generate the digital output signal; and
generate a quantization error signal,
wherein the ADC is further configured to, in a feedback loop:
provide the integrated signal and the quantization error signal as the subtrahend signals to the integrator.

2. The ADC according to claim 1, wherein the quantizer comprises a successive approximation register (SAR) ADC.

3. The ADC according to claim 1, wherein the integrator generates the integrated signal by integrating a difference of the analog input signal and the subtrahend signals.

4. The ADC according to claim 1, wherein the ADC is based on a multi-bit sigma-delta quantization.

5. A cascaded analog-to-digital converter (ADC), configured to convert an analog input signal to a digital output signal, the cascaded ADC comprising:
a first loop comprising:
a first loop integrator configured to generate a first loop integrated signal based on the analog input signal and a first loop subtrahend signal; and
a first loop quantizer comprising a successive approximation register (SAR) ADC, the first loop quantizer being configured to:
receive the first loop integrated signal from the first loop integrator,
generate a first loop digital output signal; and
generate a first loop quantization error signal that is provided as a second loop input signal to a second loop of the cascaded ADC;
the second loop comprising:
a second loop integrator configured to generate a second loop integrated signal based on the second loop input signal and a second loop subtrahend signal; and
a second loop quantizer configured to:
receive the second loop integrated signal from the second loop integrator; and
generate a second loop digital output signal,
wherein the cascaded ADC is further configured to:
provide as the first loop subtrahend signal a first analog output signal of the first loop quantizer to the first loop integrator, and
provide as the second loop subtrahend signal a second analog output signal of the second loop quantizer to the second loop integrator.

6. The cascaded ADC according to claim 5, wherein the cascaded ADC is a Multi-Stage Noise Shaping (MASH), Sigma-Delta ADC.

7. The cascaded ADC according to claim 5, wherein the cascaded ADC is based on a multi-bit sigma-delta quantization.

8. A cascaded analog-to-digital converter (ADC), configured to convert an analog input signal to a digital output signal, the cascaded ADC comprising:
a first loop comprising:
a first loop integrator configured to generate a first loop integrated signal based on the analog input signal and a first loop subtrahend signal; and
a first loop quantizer comprising a successive approximation register (SAR) ADC, the first loop quantizer being configured to:
receive the first loop integrated signal from the first loop integrator,
generate a first loop digital output signal; and
generate a first loop quantization error signal that is provided as a second loop input signal to a second loop of the cascaded ADC;
the second loop comprising:
second loop integrator configured to generate a second loop integrated signal based on the second loop input signal and a second loop subtrahend signal; and
a second loop quantizer configured to:
receive the second loop integrated signal from the second loop integrator; and
generate a second loop digital output signal,
wherein the cascaded ADC is further configured to:
provide as the first loop subtrahend signal a first analog output signal based on the first loop digital output signal and the second loop digital output signal to the first loop integrator, and
provide as the second loop subtrahend signal a second analog output signal of the second loop quantizer to the second loop integrator.

9. The cascaded ADC according to claim 8, wherein the cascaded ADC is a Sturdy Multi-Stage Noise Shaping, (SMASH) Sigma-Delta ADC.

10. The cascaded ADC according to claim 8, wherein the cascaded ADC is based on a multi-bit sigma-delta quantization.

11. An electronic device comprising the ADC according to claim 1.

12. The electronic device according to claim 11, wherein the electronic device is selected from mobile communication devices, smartphones, wearable devices, and/or sensors.

13. An electronic device comprising the cascaded ADC according to claim 5.

14. The electronic device according to claim 13, wherein the electronic device is selected from mobile communication devices, smartphones, wearable devices, and/or sensors.

15. An electronic device comprising the cascaded ADC according to claim 8.

16. The electronic device according to claim 15, wherein the electronic device is selected from mobile communication devices, smartphones, wearable devices, and/or sensors.
